(19) United States
(12) Patent Application Publication
(10) Pub. No.: US 2014/0367676 A1
(43) Pub. Date: Dec. 18, 2014

(54) PROCESS FOR THE PRODUCTION OF ELECTRICALLY SEMICONDUCTING OR CONDUCTING METAL-OXIDE LAYERS HAVING IMPROVED CONDUCTIVITY

(71) Applicant: Merck Patent GmbH, Darmstadt (DE)

(72) Inventors: Marc Haeming, Darmstadt (DE); Andreas Klyszcz, Darmstadt (DE); Klaus Bonrad, Alsbach-Haehnlein (DE); Peer Kirsch, Seeheim-Jugenheim (DE); Alexander Issanin, Rossdorf (DE); Daniel Walker, Griesheim (DE)

(73) Assignee: MERCK PATENT GMBH, Darmstadt (DE)

(21) Appl. No.: 14/374,250

(22) PCT Filed: Jan. 10, 2013
(86) PCT No.: PCT/EP2013/000063

§ 371 Date: Jul. 24, 2014

(30) Foreign Application Priority Data
Jan. 27, 2012 (DE) 102012001508.9
Mar. 27, 2012 (DE) 102012006045.9

(51) Int. Cl. H01L 29/786; H01L 21/02; H01L 29/66

(52) U.S. Cl. CPC H01L 29/7869; H01L 29/66969; H01L 21/02565; H01L 21/02664; H01L 21/02628
USPC 257/43; 438/104

(57) ABSTRACT

The invention relates to a process for the production of electrically semiconducting or conducting metal-oxide layers having improved conductivity which is suitable, in particular, for the production of flexible thin-film transistors, to metal-oxide layers produced thereby, and to the use thereof for the production of electronic components.

The invention relates to a process for the production of electrically semiconducting or conducting metal-oxide layers having improved conductivity which are suitable, in particular, for the production of flexible thin-film transistors, to metal-oxide layers produced thereby, and to the use thereof for the production of electronic components.

The production of electrically semiconducting or conducting metal-oxide layers for electronic components, in particular for printed electronic components, for example thin-film transistors or RFID (=radio frequency identification) chips, is known per se.

Since these are mass-produced articles, production processes are desirable by which the corresponding components can be produced rapidly and inexpensively in good quality. Printing processes, in particular, are therefore highly suitable.

In order to be able to employ such printing processes for the production of electrically semiconducting or conducting metal-oxide layers, the metal oxides for the production process must be in printable form, i.e. dissolved or at least pasty form.

For this reason, the production of electrically semiconducting metal-oxide layers has already been proposed from dissolved organometallic metal precursors which can be converted into the desired metal oxides without leaving a residue in a later process step.

Thus, WO 2009/010142 A2 proposes a functional material for electronic components which comprises an organometallic zinc complex which contains at least one ligand from the class of the oximates and is free from alkali metals and alkaline-earth metals. Non-porous zinc-oxide layers are obtained from this material which, depending on the specific composition, may have electrically insulating or semiconducting or conducting properties and are suitable for the production of printed electronic components.

WO 2010/078907 A1 discloses a functional material for electronic components which comprises organometallic complexes of aluminium, gallium, neodymium, ruthenium, magnesium, hafnium, zirconium, indium and/or tin which likewise contain at least one ligand from the class of the oximates.

In the above-mentioned documents, solutions of the organic metal complexes are applied to a substrate as a layer in a desired thickness and subsequently converted into the metal oxides by various measures. Depending on the coating method selected, the desired layer thickness here may also only be achieved after multiple application of the precursor materials. Due to the subsequent conversion step into the corresponding metal oxides, a uniform metal-oxide layer having predetermined thickness and material properties, which are inevitably determined by the type of material and the thickness, is formed.

Although metal-oxide layers of different conductivity can be produced in good quality using the materials and processes available in the prior art, there continues to be a demand for electrically semiconducting or conducting metal-oxide layers which can be produced from metal-oxide precursor compounds, usually dissolved, which are suitable for common coating methods, and have comparatively high charge-carrier mobility and high electrical conductivity.

The object of the invention is therefore to provide a process for the production of electrically semiconducting or conducting metal-oxide layers from precursor compounds which are suitable for use in coating methods, which results in metal-oxide layers which can be varied in composition and layer thickness and have better values with respect to their charge-carrier mobility and electrical conductivity than the metal-oxide layers available by the processes of the prior art, in particular for use in printable electronic components.

A further object of the present invention is to provide the improved metal-oxide layers which can be produced by the said process.

In addition, an object of the invention is to indicate the use of the metal-oxide layers produced in this way.

Surprisingly, it has now been found that the above-mentioned objects of the invention can be achieved by modification of the processes known to date for the production of semiconducting or conducting metal-oxide layers from organometallic precursor compounds, without adversely affecting the surface properties of the layers produced or significantly increasing the complexity for mass production.

The object of the invention is therefore achieved by a process for the production of electrically semiconducting or conducting metal-oxide layers, in which a metal-oxide precursor solution or dispersion which comprises one or more organometallic compounds is
a) applied to a substrate as a layer,
b) optionally dried, and the resultant metal-oxide precursor layer is
c) converted into a metal-oxide layer thermally, by means of treatment with UV and/or IR radiation, or by means of a combination of two or more thereof, and
d) optionally cooled,

where steps a) to d) are carried out at least twice one after the other in the same place on the substrate, where a multiple layer of metal oxides is produced.

The object of the invention is furthermore also achieved by electrically semiconducting or conducting multiple layers of metal oxides which have been produced by the said process according to the invention.

In addition, the object of the invention is also achieved by the use of the electrically semiconducting or conducting multiple layers of metal oxides produced in accordance with the invention for the production of electronic components, in particular for the production of field-effect transistors (FETs), preferably printable thin-film transistors (TFTs).

In accordance with the invention, the production of electrically semiconducting or conducting metal-oxide layers is carried out from organometallic precursor compounds thereof dissolved in solvents or dispersed in liquid dispersion media, i.e. from metal-oxide precursor solutions or metal-oxide precursor dispersions, which can be converted comparatively simply into coating compositions or printing inks which can be employed in common coating and printing processes for mass production.

Although many of the known organometallic precursor compounds of semiconducting or conducting metal oxides (i.e. organometallic compounds which decompose into volatile constituents, such as carbon dioxide, acetone, etc., and into the desired metal oxides on subsequent treatment, which takes place thermally and/or by means of actinic radiation (UV and/or IR)) are suitable for the process according to the invention, preference is given for the purposes of the present invention to the use of organometallic compounds which are metal carboxylate complexes of the metals aluminium, magnesium, gallium, neodymium, ruthenium, hafnium, zirconium, indium, zinc, titanium and/or tin having the coordination numbers 3 to 6, each of which has at least one ligand from the group of the mono-, di- or polycarboxylic acids, or derivatives of mono-, di- or polycarboxylic acids, in particular alkoxyiminocarboxylic acids (oximates), or also metal complexes of the said metals with enolate ligands, where the term “metals” is, in accordance with the invention, taken to mean the above-mentioned elements, which can either have metal or semimetal or also transition-metal properties.

Particular preference is given to the use of mixtures of metal carboxylate complexes or metal enolates of at least two different metals of those mentioned.

In particular, the at least one ligand is a 2-(methoxyimino)alkanoate, a 2-(ethoxyimino)alkanoate or a 2-(hydroxyimino)alkanoate, which are likewise called oximates below. These ligands are synthesised by condensation of alpha-keto acids or oxocarboxylic acids with hydroxylamines or alkyl-hydroxylamines in the presence of bases in aqueous or methanolic solution.

The ligand employed is likewise preferably an enolate, in particular acetyl-acetonate, which is also usual for other industrial purposes in the form of acetylacetonate complexes of various metals and is therefore commercially available.

Preferably, all ligands of the metal carboxylate complexes employed in accordance with the invention are alkoxyiminocarboxylic acid ligands, in particular those mentioned above, or complexes in which the alkoxyiminocarboxylic acid ligands are merely additionally complexed with H₂O, but otherwise no further ligands are present in the metal carboxylate complex.

The metal acetylacetonates described above are also preferably complexes which likewise contain no further ligands apart from acetylacetonate.

The preparation of the metal carboxylate complexes having alkoxyiminocarboxylic acid ligands which are preferably employed in accordance with the invention has already been described in greater detail in the above-mentioned specifications WO 2009/010142 A2 and WO 2010/078907 A1. To this extent, the documents mentioned are incorporated herein in their full scope by way of reference.

In general, the metal-oxide precursors, i.e. the aluminium, magnesium, gallium, neodymium, ruthenium, hafnium, zirconium, indium, zinc, titanium and/or tin complexes, form at room temperature by reaction of an oxocarboxylic acid with at least one hydroxylamine or alkylhydroxylamine in the presence of a base, such as, for example, tetraethylammonium hydrogencarbonate or sodium hydrogencarbonate, and subsequent addition of an inorganic aluminium, magnesium, gallium, neodymium, ruthenium, hafnium, zirconium, indium, zinc, titanium and/or tin salt, such as, for example, aluminium nitrate nonahydrate, gallium nitrate hexahydrate, anhydrous neodymium trichloride, ruthenium trichloride hexahydrate, magnesium nitrate hexahydrate, zirconium oxochloride octahydrate, hafnium oxochloride octahydrate, anhydrous indium chloride and/or tin chloride pentahydrate. Alternatively, an oxocarboxylic acid can be reacted with a hydroxocarbonate of magnesium, hafnium or zirconium, such as, for example, hydromagnesite Mg₅(CO₃)₄(OH)₂.4H₂O, in the presence of at least one hydroxylamine or alkylhydroxylamine.

The oxocarboxylic acid employed can be all representatives of this class of compound. However, preference is given to the use of oxoacetic acid, oxopropionic acid or oxobutyric acid.

The said organometallic metal-oxide precursor compounds (precursors) are, in accordance with the invention, preferably employed in dissolved or dispersed form. For this purpose, they are dissolved in suitable solvents or dispersed in suitable dispersion media in suitable concentrations, which must in each case be set to match the coating method to be employed and the number and composition of the metal-oxide precursor layers to be applied.

Suitable solvents or dispersion media here are water and/or organic solvents, for example alcohols, carboxylic acids, esters, ethers, aldehydes, ketones, amines, amides or also aromatic compounds. It is also possible to employ mixtures of a plurality of organic solvents or dispersion media or mixtures of water with organic solvents or dispersion media.

The metal carboxylate complexes having alkoxyiminocarboxylic acid ligands (oximates) already described above are preferably dissolved in 2-methoxyethanol or tetrahydrofuran.

For the purposes of the invention, suitable concentrations for a solution or dispersion in one of the above-mentioned solvents or dispersion media are regarded as being concentrations in the range from 0.01 to 70% by weight, based on the weight of the solution or dispersion. These are, as described above, in each case based on the conditions dictated by the coating method selected, matched to the viscosity of the solvents or dispersion media and to the number and composition of the metal-oxide layers to be produced in the metal-oxide multiple layer according to the invention. The principle applies here that it is advantageous, on use of the same solvent and thus the same viscosity, to reduce the concentration of metal-oxide precursor material used for each individual application step with increasing number of metal-oxide layers. By contrast, the concentration in the respective solution for the individual steps can increase if a smaller number of layers is applied for the multiple layer.

Thus, for example in the case of the spin-coating method preferably used, very low concentrations in the range from 0.1 to 10% by weight, in particular from 0.4 to 5% by weight, based on the weight of the solution or dispersion, are advantageously employed. It has been found here, surprisingly, that, on application of IZO layers, the total achievable charge-carrier mobility increases with increasing number of layers with the concentration decreasing at the same time. Thus, for example, the highest achievable charge-carrier mobility at a concentration of 3% by weight is achieved from 3 layers (about 9 cm²/Vs), whereas, in the case of a 0.6% by weight precursor solution, it is only achieved from 10 layers, but overall is significantly higher (about 16 cm²/Vs).

The metal-oxide precursor solution or dispersion is firstly applied to the respective substrate as a single layer, giving a metal-oxide precursor layer, which is subsequently optionally dried and then converted into a metal-oxide layer using suitable measures, i.e. thermally and/or with the aid of actinic radiation (treatment with UV and/or IR radiation), where any desired combinations of two or more of the above-mentioned measures can be employed.

The conversion of the precursors into metal oxides is preferably carried out by means of thermal treatment. The thermal treatment is carried out at temperatures in the range from 50° C. to 700° C. The temperatures used are advantageously in the range from 150° C. to 600° C., in particular from 180° C. to 500° C. The temperature treatment is carried out in air or under protective gas.

The temperature actually used is determined by the type of materials employed.

Thus, for example, the thermal conversion of indium and tin oximate complex precursors into an indium tin oxide layer having conducting properties is carried out at a temperature ≧150° C. The temperature is preferably between 200 and 500° C.

The thermal conversion of indium, gallium and zinc oximate complex precursors into an indium gallium zinc oxide layer having semiconducting properties is likewise carried out at a temperature ≧150° C. The temperature is preferably between 200 and 500° C.

The thermal conversion of zinc and tin oximate complex precursors into a zinc tin oxide layer having semiconducting properties is also carried out at a temperature ≧150° C., preferably between 180 and 520° C.

Cooling of the substrate coated and thermally treated in advance can optionally be carried out before the next coating step.

In addition or as an alternative to the thermal treatment, irradiation with actinic radiation, i.e. with UV and/or IR radiation, can also be carried out. In the case of UV irradiation, wavelengths <400 nm, preferably in the range from 150 to 380 nm, are employed. IR radiation can be employed with wavelengths of >800 nm, preferably from >800 to 3000 nm. This treatment also causes the organometallic precursors to decompose and volatile organic constituents and possibly water to be released, so that a metal-oxide layer remains on the substrate.

In the case of the said methods for the conversion of the metal-oxide precursor layer into a metal-oxide layer, volatile organic constituents and possibly water being liberated are removed completely. A homogeneous metal-oxide layer having uniform thickness, low porosity, homogeneous composition and morphology at the same time as an evenly flat and non-porous layer surface is formed, in particular from the metal carboxylate complexes having alkoxyiminocarboxylic acid ligands already described above and preferably employed. Depending on the choice of the metal-oxide precursor solution or dispersion and the process for the conversion of the metal-oxide precursor layer into a metal-oxide layer, the metal-oxide layer formed may be crystalline, nanocrystalline or amorphous.

In accordance with the invention, the application and conversion step described is carried out at least twice one after the other in the same place on the substrate with formation of a multiple layer of metal oxides.

Thus, at least 2 and up to 30, preferably 2 to 10, and in particular 3 to 8 metal-oxide layers are applied one above the other to the substrate as multiple layer.

It is of crucial importance for the success of the present invention that each layer is applied individually and converted into the corresponding metal oxide or mixed metal oxide before the next metal-oxide precursor layer is applied and itself converted into the corresponding metal oxide or mixed oxide. In this way, layer-by-layer growth of the multiple metal-oxide layer formed occurs. It has been found, surprisingly, that the very thin, but very homogeneous individual metal-oxide layers formed with the aid of the process according to the invention and the interfaces between the respective metal-oxide layers or mixed metal-oxide layers have a considerable influence on the charge-carrier mobility within the metal-oxide multiple layer formed and thus on its conductivity, even if a total layer thickness of the multiple layer which is the same as the layer thickness of an individual layer produced in a single process step in accordance with the prior art is obtained with the aid of the process according to the invention with identical materials for each individual layer. In any case, the process according to the invention results in increased charge-carrier mobility and thus improved electrical conductivity of the multiple layer formed, even with otherwise identical materials and layer thicknesses.

The material composition of the individual layers is variable. The multiple layer produced in accordance with the invention consists of at least two metal-oxide layers, where the first metal-oxide layer has a composition which may be identical to or different from the composition of each other metal-oxide layer. It is thus possible for a plurality of identical, a plurality of different or also a plurality of identical metal-oxide layers in combination with one or more different metal-oxide layers to be present in the metal-oxide multiple layer.

Each individual layer here consists either of an oxide of a single metal or alternatively of a mixed oxide of at least two to at most 5 elements, selected from the said metals. The mixing ratio of the individual metal elements in the mixed oxide can be varied here as required. The proportion of a second and each further metal element is preferably at least in each case 0.01% by weight, based on the total weight of the mixed oxide.

Suitable metal oxides for the purposes of the present invention are oxides and mixed oxides of aluminium, magnesium, gallium, neodymium, ruthenium, hafnium, zirconium, indium, zinc, titanium and/or tin. Of particular importance here are ZnO, doped zinc oxides, and the mixed oxides ITO (indium tin oxide), IZO (indium zinc oxide), ZTO (zinc tin oxide), IGZO (indium gallium zinc oxide), but also indium zinc oxide which is additionally doped with Hf, Mg, Zr, Ti or Ga (Hf-IZO, Mg-IZO, Zr-IZO, Ti-IZO and Ga-IZO) and dopings or mixtures of the said oxides or mixed oxides with the other metals mentioned above, for example with neodymium.

At least one layer of the metal-oxide multiple layer produced in accordance with the invention preferably consists of a mixed oxide or doped metal oxide comprising two or more of the elements selected from the group of the metals aluminium, magnesium, gallium, neodymium, ruthenium, hafnium, zirconium, indium, zinc, titanium and/or tin.

It is also possible for all layers of the metal-oxide multiple layer to consist of the said mixed oxides or doped metal oxides, in which case the composition can change from layer to layer. To this extent, the material composition of the metal-oxide multiple layer produced by the process according to the invention can be adjusted in a very variable manner, which at the same time also has effects on precise adjustability of the electrically conducting properties of the multiple layer.

Besides the material composition of the individual metal-oxide layers, their achievable layer thickness can also be adjusted in a variable manner, to be precise via the concentration of the precursor solution or dispersion to be applied, the viscosity of the precursor solution or precursor dispersion employed and the technical parameters of the application method selected. If, for example, a spin-coating method is selected, these are, inter alia, the rotational speed and duration.

The total thickness of the metal-oxide multiple layer produced in accordance with the invention is 1 nm to 1 μm, preferably 3 nm to 750 nm. The thickness of the individual layers here varies from a layer thickness which is only a single atomic layer, up to a layer thickness of 500 nm, depending on the number of layers and materials selected. The thickness of the individual layers is preferably 1 nm to 50 nm.

The thickness of the first layer here may be identical to or different from the layer thickness of each other metal-oxide layer in the metal-oxide multiple layer produced in accordance with the invention. It goes without saying that a plurality of layers of identical thickness may be present here alongside a layer of different thickness, and vice versa. As for the choice of material for the individual layers, their respective layer thickness also contributes to the accurate adjustability of the electrically conducting properties of the metal-oxide multiple layer.

The application of the individual metal-oxide precursor layers for the metal-oxide multiple layer to a substrate by the process according to the invention can be carried out by means of various known coating and printing methods. Particularly suitable for this purpose are a spin-coating method, a blade-coating method, a wire-coating method or a spray-coating method, or also conventional printing methods, such as ink-jet printing, flexographic printing, offset printing, slot die coating and screen printing. Particular preference is given here to the spin-coating method and the ink-jet method.

Suitable substrates are solid substrates, such as glass, ceramic, metal or plastic, but also, in particular, flexible substrates, such as plastic films or metal foils. In the case where the process according to the invention is employed for the production of semiconducting or conducting metal-oxide layers in thin-film transistors (TFTs), the substrate to be coated may also consist of the conventional substrate for TFTs or field-effect transistors (FETs), namely of a dielectric-coated conductive layer, the so-called “gate”, on which metal electrodes (“source” and “drain”, preferably made from gold) are located. In this case, the substrate to be coated directly with a semiconducting layer consists of a layer structure on the surface of which both a dielectric material (preferably SiO₂) and also the metal electrodes are located.

The present invention also relates to an electrically semiconducting or conducting multiple layer of metal oxides which has been produced by the process according to the invention.

The layer structure, the material composition and the layer-thickness ratios of a metal-oxide multiple layer produced in this way have already been described in detail above. According to the above description, it also goes without saying that the term “metal oxide” for the metal-oxide multiple layer according to the invention encompasses pure metal oxides, mixed metal oxides and doped metal oxides and doped mixed metal oxides.

The present invention also relates to the use of the electrically semiconducting or conducting multiple layer of metal oxides described above for the production of electronic components, in particular for the production of semiconducting or conducting functional layers for these components.

Suitable electronic components here are, in particular, field-effect transistors (FETs), such as the thin-film transistors (TFTs) preferably employed.

The term “field-effect transistor (FET)” is taken to mean a group of unipolar transistors in which, in contrast to bipolar transistors, the charge transport is dominated by only one type of charge-electrons or holes depending on the design. The most widespread type of FET is the MOSFET (metal-oxide semiconductor FET).

The FET has three connections:
source
gate
drain

In the MOSFET, a fourth connection, bulk (substrate), is also present. In the case of single transistors, this is already connected internally to the source connection and is not connected separately.

In accordance with the invention, the term “FET” generally encompasses the following types of field-effect transistor:
junction field-effect transistor (JFET)
Schottky field-effect transistor (MESFET)
metal-oxide semiconductor FET (MOSFET)
high electron mobility transistor (HEMT)
ion-sensitive field-effect transistor (ISFET)
thin-film transistor (TFT)

Preference is given in accordance with the invention to the TFT, with which large-area electronic circuits can be produced.

As already described above, the above-mentioned electronic components are preferably a field-effect transistor or thin-film transistor which is built up from a conductive layer (gate), an insulating layer, a semiconductor and electrodes (drain and source).

The gate preferably consists of a high-n-doped silicon wafer, a high-n-doped silicon thin layer, conductive polymers (for example polypyrrole-polyaminobenzenesulfonic acid or polyethylenedioxythiophene-polystyrene-sulfonic acid (PEDOT-PSS)), conductive ceramics (for example indium tin oxide (ITO) or Al-, Ga- or In-doped tin oxide (AZO, GZO, IZO), and F- or Sb-doped tin oxide (FTO, ATO)) or metals (for example gold, silver, titanium, zinc), depending on the design as a thin layer or substrate material. Depending on the design, the thin layers can be applied in the arrangement below (bottom gate) or above (top gate) of the semiconducting or insulating layer.

The electronic component preferably has an insulating layer which consists of polymers (for example poly(4-vinylphenol), polymethyl methacrylate, polystyrene, polyimides or polycarbonate) or ceramics (for example silicon dioxide, silicon nitride, aluminium oxide, gallium oxide, neodymium oxide, magnesium oxide, hafnium oxide, zirconium oxide).

The electronic component preferably has a semiconducting layer which consists of a multiple layer of metal oxides, produced by the process according to the invention.

In the same way, the conductive layer may also represent a multiple layer of metal oxides produced with the aid of the process according to the invention.

The electronic component according to the invention furthermore also contains source and drain electrodes, which can preferably consist of a high-n-doped silicon thin layer, conductive polymers (for example polypyrrole-polyaminobenzenesulfonic acid or polyethylenedioxythiophene-polystyrene-sulfonic acid (PEDOT-PSS)), conductive ceramics (for example indium tin oxide (ITO) or Al-, Ga- or In-doped tin oxide (AZO, GZO, IZO), and F- or Sb-doped tin oxide (FTO, ATO)) or metals (for example gold, silver, titanium, zinc). The electrodes (in accordance with the invention, preferably in the form of thin layers) may, depending on the design, be applied in the arrangement below (bottom contact) or above (top contact) of the semiconducting or insulating layer.

Suitable non-conductive substrates for these electronic components here are likewise solid substrates, such as glass, ceramic, metal or plastics, but in particular flexible substrates, such as plastic films and metal foils.

The process according to the invention for the production of electrically semiconducting and conducting layers results in a semiconducting or conducting multiple layer of metal oxides which is very variable both with respect to the material composition and also with respect to the layer thicknesses which can be set and thus allows specific setting of the desired properties with respect to the electrical conductivity. In addition, semiconducting or conductive metal-oxide layers which, with the same material and identical thickness, have increased electrical conductivity and increased charge-carrier mobility compared with single layers produced using known one-layer processes of the prior art can be produced with the aid of the process according to the invention. In addition, the number of defects in the individual layers and thus also in the layer as a whole is reduced, and the surface nature of the layer as a whole is significantly smoother than in the case of application of individual layers, which in turn has a positive effect on the conducting or semiconducting properties of the resultant electronic components. Thus, for example, the surface roughness for an application concentration of an IZO precursor of 3% by weight can be reduced from Rₐ=0.72 nm in the case of a single application to Rₐ=0.52 nm in the case of a double application. A reduced concentration has an equally advantageous effect in the case of an increasing number of layers. Thus, 5-fold application of a 0.5% by weight IZO precursor solution results in a surface roughness of only Rₐ=0.43 nm.

The process according to the invention thus enables, in a simple and inexpensive manner, the mass production of very effective electronic components, in particular TFTs.

The electrical conductivity can be determined by means of a four-probe direct-current method. This measurement method is described in DIN 50431 or ASTM F43-99.

The characterisation and determination of characteristic parameters of semiconducting materials, in particular also the charge-carrier mobility μ, can be carried out by means of the measurement and evaluation methods described in IEEE 1620.

The following examples are intended to illustrate the present invention. However, they should in no way be regarded as limiting. All compounds or components which can be used in the preparations are either known and commercially available or can be synthesised by known methods.

### EXAMPLES

### Example 1

### Production of a Metal-Oxide TFT Having a Single Semiconductor Layer from a 10% by Weight IZO (Indium Zinc Oxide) Precursor Solution Based on Oximate Precursors (Comparative Example)

A 10% by weight solution of 0.10 g of zinc oximate in 0.90 g of 2-methoxyethanol is mixed with a 10% by weight solution of 0.10 g of indium oximate in 0.90 g of 2-methoxyethanol in such a way that the In:Zn molar ratio in the mixture is 1.5:1. This mixture is mixed homogeneously for about 5 minutes in an ultrasound bath. If necessary, a filtration (pore size 20 μm) can be carried out subsequently. Prefabricated SiO₂/Si substrates which contain a plurality of prefabricated TFT channels including “source” and “drain” contacts comprising an Au/ITO double layer (d=40 nm) are employed. These are cleaned in acetone, isopropanol and an air plasma (8 mbar). A semiconducting IZO layer is subsequently applied to the substrate prepared in this way, with the following process being carried out once:

application of the precursor solution by spin coating (30 s, 3000 rpm),

drying at room temperature (10 s),

thermal treatment at 450° C. (4 min),

cooling to room temperature.

The electrical transport measurement is carried out with the aid of an Agilent B 1500 A and is depicted in FIGS. 1 and 2. The effective charge-carrier mobility of the transistor obtained is 0.9 cm²/Vs.

The effective charge-carrier mobility μ is determined from the transfer curve 1b using the equation

$$μ = \frac{2 L}{W {C}_{ox}} \frac{\partial \sqrt{{I}_{D}}}{\partial {V}_{G}}$$

### Example 2

### Production of Metal-Oxide TFTs Having a Multiple Semiconductor Layer from IZO Precursor Solutions Based on Oximate Precursors

Analogously to Example 1, x % by weight IZO precursor solutions are prepared, where x has the values 0.01; 0.10; 1.0; 3.0; 5.0; 10 and 15. The substrates prepared as in Example 1 are coated with IZO precursor solutions by repeated performance of the process steps described in Example 1 and converted successively into a multiple IZO layer. The electrical transport measurements and the calculation of the effective charge-carrier mobility μ are carried out analogously to Example 1 on four transistors of the same design on the same substrate.

FIG. 2 shows the effective charge-carrier mobility for the application of 2, 3 and 5 layers of different concentration compared with the single IZO layer in accordance with Example 1. The total thickness of the IZO films is 25 nm (monolayer), 37 nm (double layer), 20 nm (triple layer), 25 nm (quintuple layer).

The effective charge-carrier mobility μ increases with increasing number of metal-oxide layers or interfaces.

### Example 3

### Production of a Metal-Oxide TFT having a Single Semiconductor Layer from a 3.8% by weight IZO Precursor Solution Based on Acetylacetonates (Comparative Example)

A 10% by weight solution of 0.10 g of zinc acetylacetonate in 0.90 g of 2-methoxyethanol is mixed with a 10% by weight solution of 0.10 g of indium acetylacetonate in 0.90 g of 2-methoxyethanol in such a way that the In:Zn molar ratio in the mixture is 1.5:1. The further course of the process proceeds analogously to Example 1. The effective charge-carrier mobility determined as described above is μ=0.4 cm²/Vs with the same dimension of the TFT as in Example 1.

### Example 4

### Production of a Metal-Oxide TFT Having a Multiple Semiconductor Layer from an IZO Precursor Solution Based on Acetylacetonates

A 1.3% by weight precursor solution is prepared analogously to Example 3. From this precursor solution, a triple IZO layer is applied to the substrate prepared in accordance with Example 1 by the process described in Example 1, which is carried out a total of three times one after the other. With the same dimension of the TFT as in Examples 1 and 3, the effective charge-carrier mobility μ=7.2 cm²/Vs and is thus significantly higher than for the IZO monolayer from Example 3.

### Example 5

### Production of a Metal-Oxide TFT Having a Triple Semiconductor Layer from an IZO and IGZO (Indium Gallium Zinc Oxide) Precursor Solution

An SiO₂ substrate is cleaned analogously to Example 1 and coated with an IZO film produced from a 10% by weight precursor solution (basis oximate) having the molar ratio (In:Zn=1.7:1). For the application of the IGZO layer, a 10% by weight solution of 0.10 g of zinc oximate in 0.90 g of 2-methoxyethanol is mixed with a 10% by weight solution of 0.10 g of indium oximate in 0.90 g of 2-methoxyethanol and a 3% by weight solution of 0.03 g of gallium oximate and 0.97 g of 2-methoxyethanol in such a way that an In:Zn:Ga molar ratio in the mixture of 1.7:1:0.3 is obtained. This precursor solution is applied to the pre-coated SiO₂ substrate in a single layer analogously to the process described in Example 1. A further coating with the 10% by weight IZO precursor solution described above is carried out subsequently.

A three-layered IZO/IGZO/IZO coating on an SiO₂ substrate is obtained. Secondary ion mass spectrometry carried out on the sample shows that a significant Ga signal is only evident in the region of the IGZO layer, which proves that diffusion of the various materials into adjacent layers does not take place and separate layers which can clearly be delimited from one another are thus obtained in the multiple layer.

### Example 6

### Printing of Multiple Semiconductor Layers in Order to Increase the Charge-Carrier Mobility of TFTs

An SiO₂/Si TFT substrate is cleaned as described in Example 1. A 3% by weight precursor mixture of 2-methoxyethanol and indium oximate and zinc oximate is prepared in the In:Zn molar ratio of 1.7:1, analogously to the procedure in Example 1. The finished precursor mixture is introduced into a cartridge of a Dimatix DMP-2831 ink-jet printer. The areas of the substrate on which the pre-structured channels of the transistor are located are then printed at room temperature (droplet size about 10 pl, jet frequency 1 kHz).

A single IZO layer is produced as follows:

printing of the substrate with the precursor solution,

drying at room temperature (10 s),

thermal treatment at 450° C. (4 min, hotplate),

cooling to room temperature on a metal plate.

A monolayer is produced by carrying out the process described once, while multiple layers are produced by repeating all process steps correspondingly frequently in the said sequence.

The transfer curves and the effective charge-carrier mobility are depicted in FIG. 3. The dimensions of the TFTs correspond to those from Examples 1 and 2. In the detail, the effective charge-carrier mobility averaged over four transistors is plotted. It is 3.4; 10.8; 14.7; 16.2 cm²/Vs from the monolayer film to the 4-layer film.

### KEY TO THE FIGURES

FIG. 1: shows a) the initial curve and b) the transfer curve of a transistor in accordance with Example 1

FIG. 2: shows a diagram of the effective charge-carrier mobility of a monolayer in accordance with Example 1 and a double layer, triple layer and quintuple layer in accordance with Example 2 with in each case adjusted concentration and with comparable total thicknesses of the layers obtained

FIG. 3: shows transfer curves of single-layered and multilayered IZO semiconductor films after production by the printing process in accordance with Example 6.

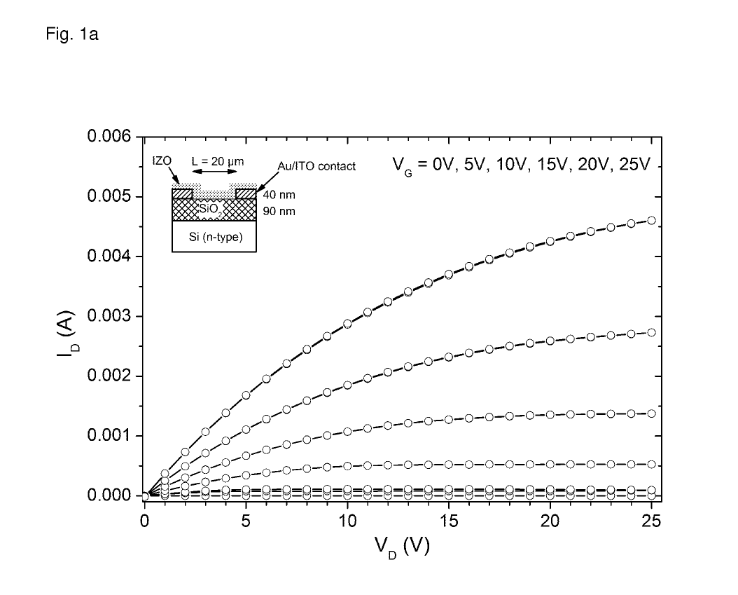

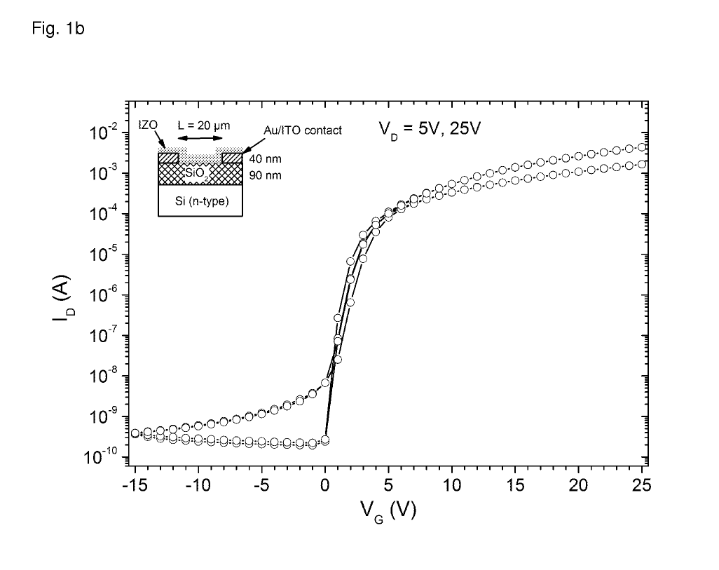

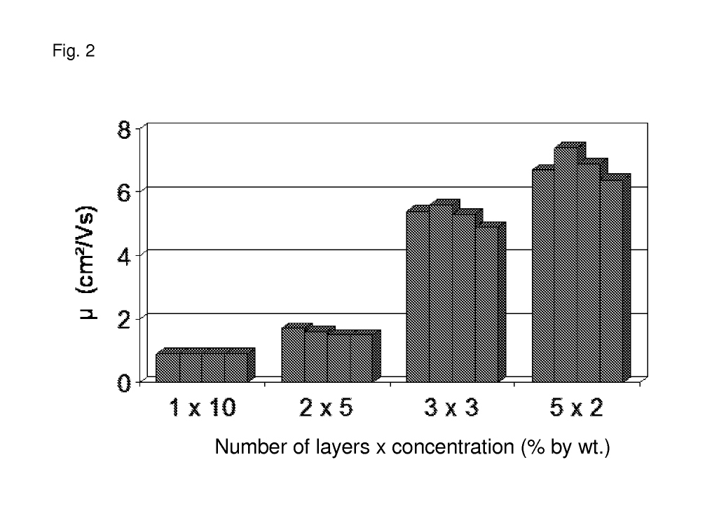

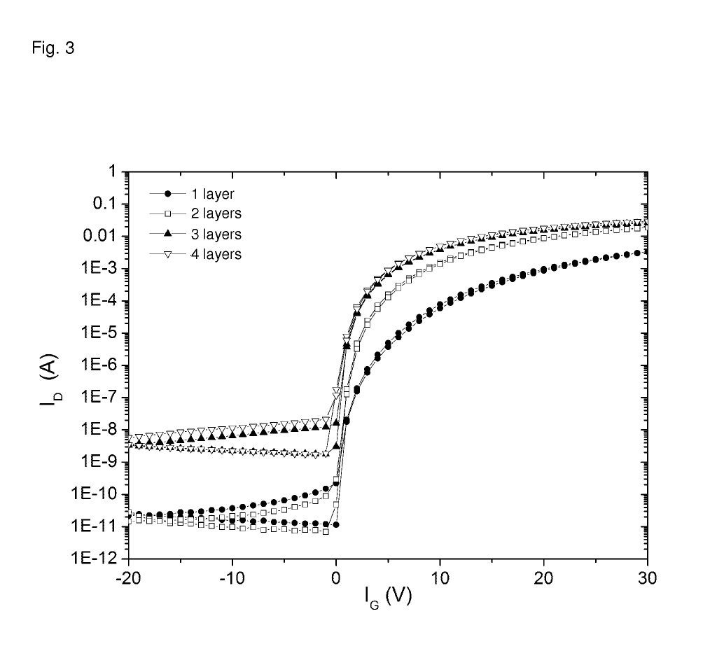

1. Process for the production of electrically semiconducting or conducting metal-oxide layers, in which a metal-oxide precursor solution or dispersion which comprises one or more organometallic compounds is
a) applied to a substrate as a layer,
b) optionally dried, and the resultant metal-oxide precursor layer is
c) converted into an oxide layer thermally, by means of treatment with UV and/or IR radiation, or by means of a combination of two or more thereof, and
d) optionally cooled,
where steps a) to d) are carried out at least twice one after the other in the same place on the substrate with formation of a multiple layer of metal oxides.

2. Process according to claim 1, characterised in that the organometallic compounds are metal carboxylate complexes of the metals aluminium, magnesium, gallium, neodymium, ruthenium, hafnium, zirconium, indium, zinc, titanium and/or tin having the coordination numbers 3 to 6, each of which has at least one ligand from the group of the mono-, di- or polycarboxylic acids, or derivatives of mono-, di- or polycarboxylic acids, in particular alkoxyiminocarboxylic acids (oximates), or are metal complexes with enolate ligands.

3. Process according to claim 2, characterised in that the at least one ligand is a 2-(methoxyimino)alkanoate, a 2-(ethoxyimino)alkanoate or a 2-(hydroxyimino)alkanoate or an acetylacetonate.

4. Process according to claim 1, characterised in that a multiple layer is produced from at least two metal-oxide layers, where the first metal-oxide layer has a composition which is identical to or different from the composition of each other metal-oxide layer.

5. Process according to claim 1, characterised in that the composition of at least one of the metal-oxide layers represents a mixed oxide of two or more of the elements selected from the group aluminium, magnesium, gallium, neodymium, ruthenium, hafnium, zirconium, indium, zinc, titanium and tin.

6. Process according to claim 1, characterised in that a multiple layer is produced from at least two metal-oxide layers, where the first metal-oxide layer has a layer thickness which is identical to or different from the layer thickness of each other metal-oxide layer.

7. Process according to claim 1, characterised in that the layer thickness of the individual metal-oxide layers is in each case in the range between a single atomic layer and 500 nm.

8. Process according to claim 1, characterised in that the application of the metal-oxide precursor layer is carried out by means of a spin-coating, blade-coating, wire-coating or spray-coating method or by means of an ink-jet printing, flexographic printing, offset printing, slot die coating or screen printing method.

9. Process according to claim 1, characterised in that the thermal treatment in step c) is carried out at a temperature in the range from 50° C. to 700° C.

10. Electrically semiconducting or conducting multiple layer of metal oxides, produced by a process according to claim 1.

11. An electronic component comprising electrically semiconducting or conducting multiple layers of metal oxides according to claim 10.

12. A component according to claim 11, which is a field-effect transistor (FET), in particular a thin-film transistor (TFT).

13. A component according to claim 11, has at least one conductive substrate or a non-conducting substrate having a conductive layer (gate), an insulator, electrodes (drain electrode and source electrode), and a semiconducting multiple layer of metal oxides.

14. A component according to claim 13, characterised in that the substrate is either a solid substrate, such as glass, ceramic, metal or plastic substrate, or a flexible substrate, in particular a plastic film or a metal foil.
